(19) United States
(12) Patent Application Publication
(10) Pub. No.: US 2012/0267987 A1
(43) Pub. Date: Oct. 25, 2012

(54) ELECTROMECHANICAL CONVERSION ELEMENT AND DRIVE DEVICE

(75) Inventor: Tomoyuki Yuasa, Osaka-shi (JP)

(73) Assignee: KONICA MINOLTA ADVANCED LAYERS, INC., Hachioji-shi, Tokyo (JP)

(21) Appl. No.: 13/518,063

(22) PCT Filed: Dec. 13, 2010
(86) PCT No.: PCT/JP2010/007233

§ 371 Date: Jun. 21, 2012

(30) Foreign Application Priority Data
Dec. 21, 2009 (JP) 2009-289184

(51) Int. Cl. H01L 41/083

(52) U.S. Cl. 310/366

(57) ABSTRACT

A piezoelectric element 1 as an electromechanical conversion element 1 and a drive device S according to the present invention include step portions 21 which are formed on each of a pair of external electrodes 11, 11 formed on outer peripheral surfaces of a laminated body 10 including a plurality of piezoelectric layers 10a and have a difference in height between the boundary of a connection region 11a for connection to a power supply member for supplying power and end sections 10c of the laminated body 10.

### CROSS REFERENCE TO RELATED APPLICATIONS

This is a U.S. national stage of application No. PCT/JP2010/007233, filed on 13 Dec. 2010. Priority under 35 U.S.C. §119(a) and 35 U.S.C. §365(b) is claimed from Japanese Application No. 2009-289184, filed 21 Dec. 2009, the disclosure of which are also incorporated herein by reference.

### TECHNICAL FIELD

The present invention relates to an electromechanical conversion element for converting electric energy into mechanical energy and particularly to the structure of external electrodes thereof. The present invention also relates to a drive device using this electromechanical conversion element.

### BACKGROUND ART

An actuator is normally incorporated in a mechanical device including a movable part to drive the movable part. This actuator is a device for converting input energy into mechanical momentum and a drive device using an electromechanical conversion element such as a piezoelectric element called a SIDM (Smooth Impact Drive Mechanism) is known as one type of an actuator.

FIG. 9 are views showing the configuration of an SIDM, wherein FIG. 9(A) is a perspective view thereof and FIG. 9(B) is an exploded perspective view thereof.

In FIG. 9, an SIDM 100 includes an electromechanical conversion element 101, a vibrating member 102 and a supporting member 103. The electromechanical conversion element 101 is an element for converting electrical energy into mechanical energy and, for example, a piezoelectric element 101 in which a plurality of piezoelectric layers 101a made of a piezoelectric material are laminated via internal electrodes 101b interposed between the respective piezoelectric layers 101a. A pair of external electrodes 101c, 101c are respectively formed on side surfaces of this piezoelectric element 101 extending in a lamination direction and facing each other, and successively and alternately connected to the plurality of internal electrodes 101b. The vibrating member 102 is a column-like member fixed to one end section of the piezoelectric element 101 in the lamination direction. The supporting member 103 is a member fixed to the other end section of the piezoelectric element 101 in the lamination direction and supporting the piezoelectric element 101 and the vibrating member 102. In the thus configured SIDM 100, when a pulsed drive voltage is applied via the pair of external electrodes 101c, 101c from an external circuit, the piezoelectric element 101 elongates and contracts in the lamination direction. In this way, the piezoelectric element 101 converts input electrical energy into mechanical elongating and contracting movements. As this piezoelectric element 101 elongates and contracts, the vibrating member 102 reciprocates in a longitudinal direction thereof. Here, if an unillustrated moving member to be frictionally engaged with the vibrating member 102 is mounted on the vibrating member 102 and the electromechanical conversion element 101 is repeatedly elongated and contracted so that the moving speed of the vibrating member 102 is asymmetric between an outward movement and a return movement, the moving member moves along the longitudinal direction and electrical energy is converted into a motion of the moving member due to this asymmetric reciprocating motion of the vibrating member 102.

Such an electromechanical conversion element 101 is, for example, disclosed in patent literature 1. In patent literature 1 is disclosed a piezoelectric ceramic actuator including a piezoelectric ceramic section in which a plurality of piezoelectric ceramics are respectively polarized by being sandwiched between positive and negative internal electrodes facing each other and so laminated that directions of the polarization are opposite to each other, and a pair of positive and negative external electrodes provided on side surfaces extending along a lamination direction of the piezoelectric ceramic section and facing each other and composed of a positive electrode connected only to the positive internal electrode and a negative electrode connected only to the negative internal electrode. A pair of external lead wires are respectively connected to the pair of positive and negative external electrodes, and both end sections of the piezoelectric ceramic section in the lamination direction are respectively fixed to a supporting section and a driven section in a driven part of a machining equipment or the like by being bonded using epoxy resin or the like.

The SIDM 100 shown in FIG. 9(A) is manufactured as follows. For example, as shown in FIG. 9(B), after a thermosetting adhesive 104, for example, containing epoxy resin is applied to a surface on one end section of the vibrating member 102 or a surface on one end section of the piezoelectric element 101, the one end section of the vibrating member 102 and the one end section of the piezoelectric element 101 are bonded. After the adhesive 104 is applied to a surface on one end section of the supporting member 103 or a surface on the other end section of the piezoelectric element 101, the one end section of the supporting member 103 and the other end section of the piezoelectric element 101 are bonded. Then, a heating treatment is carried out. The adhesive 104 is thermally cured by this heating treatment, whereby the vibrating member 102 and the supporting member 103 are fixed to the piezoelectric element 101 by the adhesive 104. In the thermal curing of the adhesive 104 by this heating treatment, a phenomenon called bleed-out (epoxy bleed-out), in which an uncured part of the adhesive 104 (uncured adhesive 104a) flows, occurs. If this bleed-out occurs, this uncured adhesive 104a may flow onto the external electrodes 101c provided on the side surfaces of the piezoelectric element 101 in relation to the application amount of the adhesive 104, the sizes of the piezoelectric element 101, the vibrating member 102 and the supporting member 103 and the like and, further, exposed surfaces of the external electrodes 101c may be covered as shown in FIG. 9(A).

A pair of lead wires need to be respectively connected to this pair of external electrodes 101c, 101c to supply electrical energy to the piezoelectric element 101 as in the piezoelectric ceramic actuator disclosed in the above patent literature 1. However, if the exposed surfaces of the external electrodes 101c are covered by the uncured adhesive 104a due to the bleed-out described above, it becomes difficult to electrically connect the lead wires and the external electrodes 101c. The lead wires and the external electrodes 101a are generally electrically connected by solder. However, if the exposed surfaces of the external electrodes 101c are partly covered, if not entirely covered, by the uncured adhesive 104a, there is a possibility of a connection failure since the exposed areas for soldering on the external electrodes 101c become smaller.

As described above, in the piezoelectric ceramic actuator disclosed in the above patent literature 1, after the pair of external lead wires are respectively connected to the pair of positive and negative external electrodes, the both end sections of the piezoelectric ceramic section in the lamination direction are respectively fixed to the supporting section and the driven section in the driven part of the machining equipment or the like by being bonded using epoxy resin or the like. Thus, an inconvenience as described above does not occur. Further, the piezoelectric ceramic section having a section size of 5 mm×5 mm and a length of 70 mm is supposed in the piezoelectric ceramic actuator disclosed in the above patent literature 1 and a sufficient area for soldering is secured.

On the other hand, the SIDM 100 has been required to be miniaturized with the miniaturization, weight saving, power saving and the like of a device incorporating this. If the SIDM 100 is miniaturized, it is difficult to secure a sufficient area for soldering, taking the bleed-out into consideration. Particularly, in the case of incorporating the SIDM 100 into an imaging device (camera) mounted in a mobile telephone, for example, to drive a focus lens and/or a zoom lens, the length of the piezoelectric element 101 in the SIDM 100 is about several mm or 1 mm and an area for soldering is originally small. Thus, a reduction in the areas of the exposed surfaces of the external electrodes 101c caused by this bleed-out is a serious problem.

### CITATION LIST

### Patent Literature

Patent literature 1: Publication of Japanese Registered Utility Model No. 2587406

### SUMMARY OF INVENTION

The present invention was developed in view of the above situation and an object thereof is to provide an electromechanical conversion element capable of suppressing a reduction in exposed areas for soldering of external electrodes caused by the bleed-out of an adhesive and more reliably securing connection areas for power supply members on the external electrodes, and a drive device using this electromechanical conversion element.

An electromechanical conversion element and a drive device according to the present invention includes a step portion which is formed on each of a pair of external electrodes formed on outer peripheral surfaces of a laminated body including a plurality of piezoelectric layers and has a difference in height between the boundary of a connection region for connection to a power supply member for supplying power and an end section of the laminated body. Accordingly, the thus configured electromechanical conversion element and the drive device can suppress a reduction in exposed areas for soldering of the external electrodes caused by the flow-out of an adhesive and more reliably secure connection areas for the power supply members on the external electrodes since the adhesive is blocked by the step portion and the flow of the adhesive to the connection region is suppressed even if the adhesive flows onto the external electrode.

The above and other objects, features and advantages of the present invention will become more apparent upon reading the following detailed description along with the accompanying drawings.

### BRIEF DESCRIPTION OF DRAWINGS

FIG. 1 is a perspective view showing the configuration of a drive device according to an embodiment,

FIG. 2 are enlarged views of an electromechanical conversion element part in the drive device shown in FIG. 1,

FIG. 3 are views explaining a bleed-out state of an adhesive,

FIG. 4 are views explaining a first modification of step sections,

FIG. 5 are views explaining a second modification of the step sections,

FIG. 6 are views explaining a third modification of the step section,

FIG. 7 is a view explaining a fourth modification of the step section,

FIG. 8 is a view showing the configuration of a drive device incorporated in an optical system, and

FIG. 9 are views showing the configuration of an SIDM.

### DESCRIPTION OF EMBODIMENTS

Hereinafter, one embodiment according to the present invention is described with reference to the drawings. Note that components denoted by the same reference signs in the respective drawings are the same components and a description thereof is omitted as appropriate. Further, in this description, components are denoted by reference signs without suffixes when being collectively called while being denoted by reference signs with suffixes when being individually distinguished.

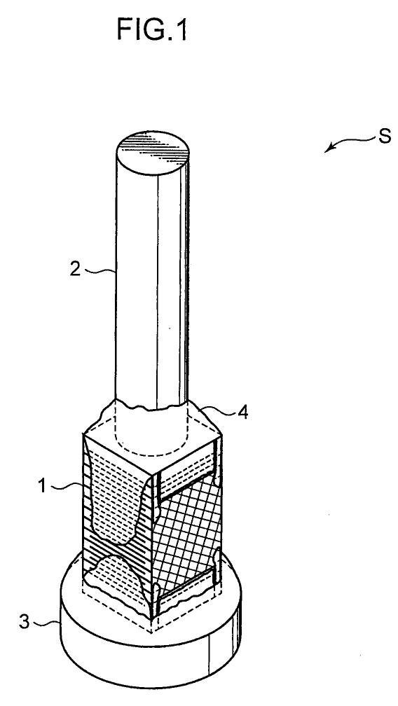

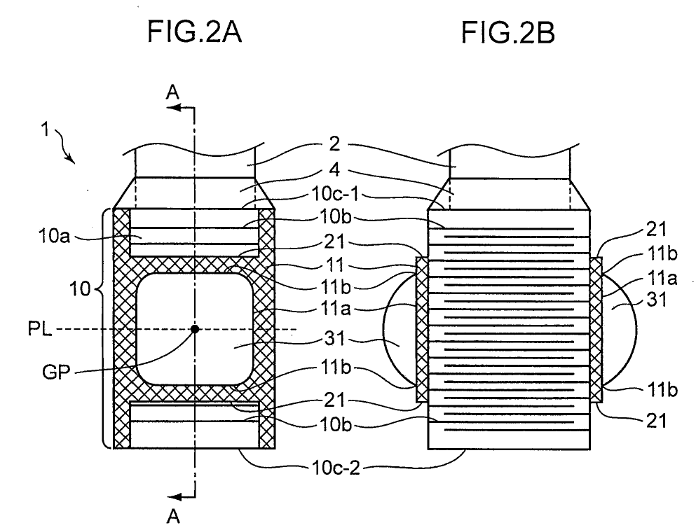

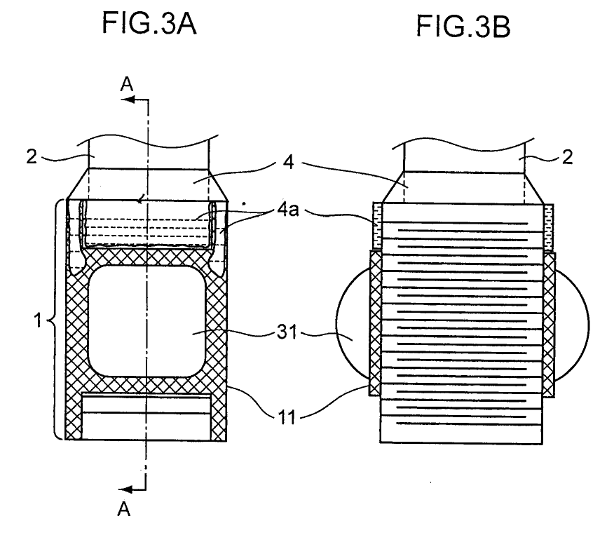

FIG. 1 is a perspective view showing the configuration of a drive device according to the embodiment. FIG. 2 are enlarged views of an electromechanical conversion element part in the drive device shown in FIG. 1. FIG. 2(A) shows an external electrode of an electromechanical conversion element and FIG. 2(B) is a sectional view along line AA of FIG. 2(A). FIG. 3 are views showing a bleed-out state of an adhesive. FIG. 3(A) shows the external electrode of the electromechanical conversion element and FIG. 3(B) is a sectional view along line AA of FIG. 3(A).

In FIG. 1, the drive device S of this embodiment includes an electromechanical conversion element 1, a vibrating member 2 and a supporting member 3.

The electromechanical conversion element 1 is an element for converting input electrical energy into mechanical motion and, for example, a piezoelectric element 1 for converting input electrical energy into mechanical elongating and contacting movements by a piezoelectric effect. This piezoelectric element 1 as the electromechanical conversion element 1 includes, for example, a laminated body 10 in which a plurality of piezoelectric layers 10a made of a piezoelectric material and a plurality of conductive internal electrode layers 10b are alternately laminated, and a pair of external electrodes 11, 11 which are formed along a lamination direction on outer peripheral surfaces of the laminated body 10 and successively and alternately electrically connected to the internal electrode layers 10a as shown in FIG. 2.

The piezoelectric material is, for example, an inorganic piezoelectric material such as so-called PZT, crystal, lithium niobate (LiNbO₃), potassium tantalate niobate (K(Ta, Nb)O₃), barium titanate (BaTiO₃), lithium tantalate (LiTaO₃) or a strontium titanate (SrTiO₃).

More specifically, the laminated body 10 is a column-like body in which the plurality of piezoelectric layers 10a are laminated with the internal electrode layers 10b interposed between the respective piezoelectric layers 10a and the respective edge sections of the internal electrode layers 10b are alternately formed along the lamination direction alternately facing to the outside on a pair of outer peripheral surfaces facing each other.

The external electrodes 11 are formed as layers (thin films) along the lamination direction on the pair of outer peripheral surfaces of the laminated body 10 facing each other, for example, by sputtering, vapor deposition or the like of a conductive metal material such as gold or copper or by screen printing of, for example, conductive resin in which metal fillers and the like are dispersed.

In the thus configured piezoelectric element 1, if electrical energy is supplied to the pair of external electrodes 11, 11, by applying a predetermined voltage to this pair of external electrodes 11, 11, from the outside, the laminated body 10 elongates or contracts in the lamination direction by the piezoelectric effect of each piezoelectric layer 10a.

The vibrating member 2 is a column-like (shaft-like) member fixed to one end section of the laminated body 10 in this piezoelectric element 1. The vibrating member 2 can be made of arbitrary materials, for example, metal, resin and carbon. A cross-section perpendicular to a longitudinal direction of the vibrating member 2 may have an arbitrary shape, for example, a rectangular, polygonal, elliptical or circular shape, but preferably has a circular shape so that a moving member is easily relatively movable along the longitudinal direction of the vibrating member 2 when the moving member is mounted on the vibrating member 2 by frictional engagement.

Further, the supporting member 3 is a member which is fixed to the other end section of the laminated body 10 in this piezoelectric element 1 and supports the piezoelectric element 1 and the vibrating member 2 by holding them. The supporting member 3 can also be made of arbitrary materials, for example, metal and resin. The supporting member 3 may be held in position by being fixed to a housing of an apparatus into which the drive device S is to be incorporated or the like, but functions as a weight of the drive device S in the case of being substantially held in position by its inertial mass. In the case of functioning as a weight of the drive device S in this way, the supporting member 3 is preferably made of a high-density material in terms of miniaturization.

Since the supporting member 3 is substantially held in position in this way, the laminated body 10 of the piezoelectric element 1 elongates and contracts with the other end section fixed to the supporting member 3 substantially as a fixed end, these elongating and contracting movements are transmitted to the vibrating member 2 and the vibrating member 2 reciprocates in tandem with the elongating and contracting movements of the laminated body 10 in this piezoelectric element 1 when the laminated body 10 of the piezoelectric element 1 elongates and contracts as described above.

Here, in this embodiment, each of the pair of external electrodes 11, 11 in this piezoelectric element 1 has a connection region 11a supposed as a region for connection to conductive power supply member for supplying power, and step sections 21 having a difference in height are formed between a boundary 11b of this connection region 11a and end sections 10c of the laminated body 1 in the lamination direction as show in FIG. 2. The step section 21 may have a predetermined height set in advance. For example, when the external electrode 11 is formed by sputtering, the step section 21 has a height, which is any value from about 200 to 600 nm, so as to be relatively easily formable by that film formation method. For example, in the case of film formation by screen printing, the step section 21 has a height, which is any value from about 1 to 50 μm, so as to be relatively easily formable by that film formation method.

An approximate region having a predetermined area including a position where the power supply member is to be connected is supposed and set as the connection region 11a in advance, and the boundary 11b of this connection region 11a may be present between the position where the power supply member is to be connected and the step section 21 and may not be clearly specified before the power supply member is connected to the connection region 11a or may be clearly specified, for example, by printing or the like or may be clearly specified by connecting the power supply member to this connection region 11a. In short, when an adhesive 4 flows toward the external electrode 11, this adhesive 4 is substantially blocked by the step section 21. In this case, a sufficient area not covered by this adhesive 4 (area where the power supply member can be mounted) only has to be secured on the external electrode 11 as the connection region 11a.

Such step sections 21 are provided by forming rectangular cutouts at end sections of the external electrode 11 in the lamination direction of the laminated body 10 so that both widthwise ends of the external electrode 11 having a predetermined width are left when the external electrode 11 is viewed in a normal direction (direction perpendicular to the lamination direction) to the outer peripheral surface of the laminated body 10 where the external electrode 11 is formed (when the external electrode 11 is planarly viewed), for example, as shown in FIG. 2(A). In an example shown in FIG. 2(A) in which rectangular parts of the external electrode 11 are cut off in this way, the outer peripheral surface of the laminated body 10 is exposed and the step sections 21 are formed by a difference in height (thickness of the external electrode 11 in the normal direction) from the outer peripheral surface of this laminated body 10 to the surface of the external electrode 11 (surface of the connection region 11a). At the step sections 21, the connection region 11a of the external electrode 11 is higher than the outer peripheral surface of the laminated body 10 by the difference in height of the step sections 21.

In the example shown in FIG. 2, there are two step sections 21, 21 between the boundary 11b of the connection region 11a and one end section 10c-1 of the laminated body 10 in the lamination direction and between the boundary 11b of the connection region 11a and the other end section 10c-2 of the laminated body 10 in the lamination direction.

In the example shown in FIG. 2, these two step sections 21, 21 are line-symmetric with respect to a predetermined line PL parallel to the end sections 10c (10c-1, 10c-2) of the laminated body 10 in the lamination direction when the external electrode 11 is viewed in the normal direction to the outer peripheral surface of the laminated body 10 and point-symmetric with respect to a gravity point GP of the external electrode 11 when the external electrode 11 is viewed in the normal direction to the outer peripheral surface of the laminated body 10. The predetermined line PL is a line equidistant from the both end sections 10c-1, 10c-2 of the laminated body 10 in the lamination direction and passes through the gravity point GP of the external electrode 11 in the example shown in FIG. 2.

The external electrode 11 including such cutouts is formed, for example, by sputtering, vapor deposition or the like using an H-shaped mask. Alternatively, the external electrode 11 having such cutouts can be formed, for example, by H-shaped screen printing.

Note that although the outer peripheral surface of the laminated body 10 is exposed in these cutouts in the example shown in FIG. 2, coatings thinner than the connection region 11a may be present in these cutouts since the step sections 21 can be formed if there is a difference in height between the surface of the connection region 11a and the surfaces of the cutouts. The coatings may be made of the same material as the external electrode 11 or a different material. That is, the step sections 21 are provided, for example, by forming rectangular recesses in the end sections of the external electrode 11 in the lamination direction of the laminated body 10 so as to leave both widthwise ends of the external electrode 11 having a predetermined width when the external electrode 11 is viewed in the normal direction to the outer peripheral surface of the laminated body 10 where the external electrode 11 is formed.

In the case of fixing the vibrating member 2 and the supporting member 3 respectively to the both end surfaces in the lamination direction of the piezoelectric element 1 including the pair of external electrodes 11, 11 each with the step sections 21, 21 using the adhesive 4, the one end section of the vibrating member 2 and the one end section of the piezoelectric element 1 are bonded after the adhesive 4 is first applied, for example, to the surface of the one end section of the vibrating member 2 or the surface of the one end section of the piezoelectric element 1, and the one end section of the supporting member 3 and the other end section of the piezoelectric element 1 are bonded after the adhesive 4 is applied to the surface of the one end section of the supporting member 3 or the surface of the other end section of the piezoelectric element 1 (bonding step).

If this adhesive 4 is made of thermosetting resin containing, for example, epoxy resin, a heating treatment is carried out following the bonding step for thermal curing. Normally, bleed-out occurs by this heating process. Even if an uncured adhesive 4a flows onto the outer peripheral surfaces of the laminated body 10 of the piezoelectric element 1 and the external electrodes 11, for example, as shown in FIG. 3, the flow of the uncured adhesive 4a is blocked by the step sections 21 to suppress the flow of the uncured adhesive 4a to the connection regions 11a, wherefore a reduction in the areas of the external electrodes 11 caused by the flow-out of the uncured adhesive 4a can be suppressed and connection areas for the power supply members on the external electrodes 11 can be more reliably secured. Particularly, when the length of the piezoelectric element 1 in the lamination direction is about several mm in relation to the amount of the adhesive 4 and the size of the piezoelectric element 1, the configuration described in this embodiment is more effective. Further, when the length of the piezoelectric element 1 in the lamination direction is about 1 mm, the configuration described in this embodiment is even more effective.

The uncured adhesive 4a flows out due to the bleed out in the above description. However, the flow of the adhesive 4a to the connection regions 11a is similarly suppressed by blocking an excessive flow of the adhesive 4a by the step sections 21 even if the adhesive 4a flows onto the outer peripheral surfaces of the laminated body 10 of the piezoelectric element 1 and the external electrodes 11 as shown in FIG. 3 because the amount of the adhesive 4 is excessive. Thus, a reduction in the areas of the external electrodes 11 caused by the flow-out of the adhesive 4a can be suppressed and the connection areas for the power supply members on the external electrodes 11 can be more reliably secured.

Thus, in the case of connecting the pair of power supply members (not shown) for supplying power, which are conductive, for example, by being made of lead wires, gold wires or the like, to the respective connection regions 11a on the pair of external electrodes 11, 11 by solder 31, the connection areas for the power supply members on the external electrodes 11, 11 are secured. Therefore, the pair of power supply members (not shown) can be connected to the respective connection regions 11a on the pair of external electrodes 11, 11 and connection failures can be reduced more than before.

Further, since the two step sections 21, 21 are line-symmetric to each other with respect to the predetermined line PL in the above piezoelectric element 1, the bonding step can be performed, ignoring upper and lower sides of the piezoelectric element 1 in the lamination direction, in the case of bonding other members, for example, the vibrating member 2 and the supporting member 3 to the piezoelectric element 1. In this way, the bonding step can be performed without managing the upper and lower sides of the piezoelectric element 1 in the lamination direction, which is advantageous in manufacturing.

Further, since the two step sections 21, 21 are point-symmetric to each other with respect to the gravity point GP of the external electrode 11 in the above piezoelectric element 1, the bonding step can be performed, ignoring upper and lower sides of the piezoelectric element 1 in the lamination direction, in the case of bonding other members, for example, the vibrating member 2 and the supporting member 3 to the piezoelectric element 1. In this way, the bonding step can be performed without managing the upper and lower sides of the piezoelectric element 1 in the lamination direction, which is advantageous in manufacturing.

Further, since the both widthwise ends of the external electrodes 11 having a predetermined width are left in forming the step sections 21 in the above piezoelectric element 1, power can be supplied also to the piezoelectric layers 10a where the cutouts are formed and a piezoelectric effect can be achieved.

Note that it is also thought to form long projections (bank sections) extending along the width direction of the external electrode 11 on the external electrode 11 between the boundary 11b of the connection region 11a and the end sections 10c of the laminated body 10 in the lamination direction to suppress the flow of the adhesive 4 to the connection region 11a. However, since the step sections 21 are provided as parts of the external electrode 11 in this embodiment, the external electrode 11 and the step sections 21 can be formed in one step. In the technique of providing the projections, not only a step of forming the external electrodes 11, but also a step of forming the projections are necessary, thereby increasing the number of steps. In this technique, the outer shape accuracy of the piezoelectric element is affected by the thickness of the projections. Further, in the case of forming the projections by screen printing of resin, the resin of the projections also bleeds out due to the heating treatment for the adhesive 4.

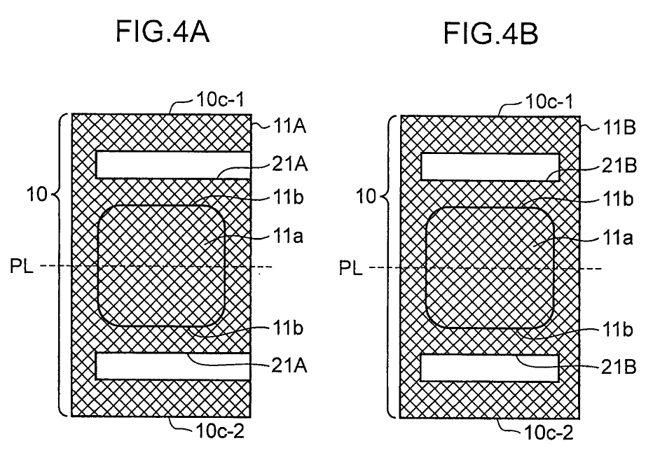

Here, although the step sections 21 are provided by forming the H-shaped external electrode 11 when the external electrode 11 is planarly viewed in the example shown in FIGS. 1 and 2, the formation thereof is not limited to this. For example, the step sections 21 may be provided by forming the external electrode 11 in various shapes shown in FIGS. 4 to 7.

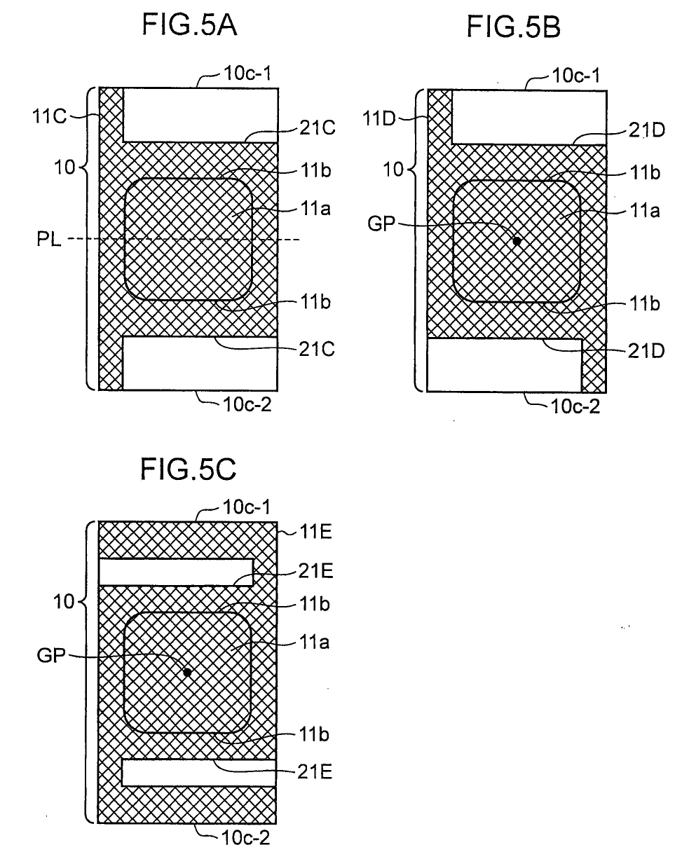

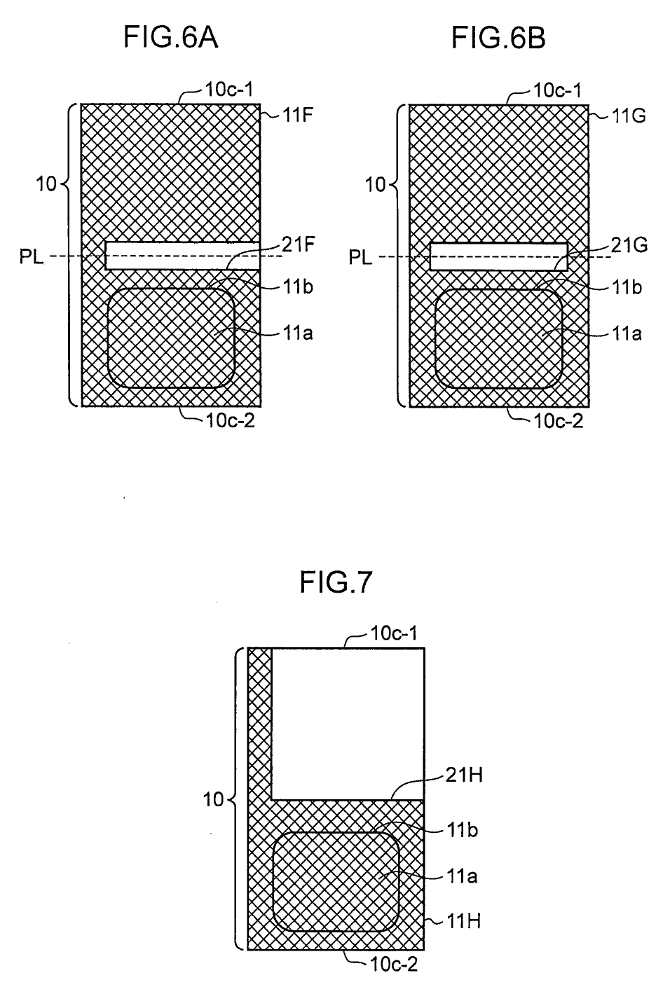

FIG. 4 are views explaining a first modification of the step sections. FIG. 4(A) shows a first configuration of the external electrode 11 and FIG. 4(B) shows a second configuration of the external electrode 11. FIG. 5 are views explaining a second modification of the step sections. FIG. 5(A) shows a third configuration of the external electrode 11, FIG. 5(B) shows a fourth configuration of the external electrode 11 and FIG. 5(C) shows a fifth configuration of the external electrode 11. FIG. 6 are views explaining a third modification of the step sections. FIG. 6(A) shows a sixth configuration of the external electrode 11 and FIG. 6(B) shows a seventh configuration of the external electrode 11. FIG. 7 is a view explaining a fourth modification of the step section and shows an eighth configuration of the external electrode 11.

For example, the step sections 21 may be provided by cutting out slits in the external electrode 11 formed to have a substantially uniform thickness. More specifically, for example, as shown in FIG. 4(A), step sections 21A are provided by forming an external electrode 11A with rectangular cutouts extending in the width direction from one widthwise end of the external electrode 11A and long in the width direction at positions inwardly of and at a predetermined distance from the end sections 10c of the laminated body 10 in the lamination direction when the external electrode 11A is planarly viewed. Alternatively, as shown in FIG. 4(B), step sections 21B are provided by cutting out rectangular openings long in the width direction in an external electrode 11B (forming rectangular openings long in the width direction in the external electrode 11B) at positions inwardly of and at a predetermined distance from the end sections 10c of the laminated body 10 in the lamination direction when the external electrode 11A is planarly viewed. In examples shown in FIGS. 4(A) and 4(B), there are two step sections 21A, 21A; 21B, 21B between the boundary 11b of the connection region 11a and the one end section 10c-1 of the laminated body 10 in the lamination direction and between the boundary 11b of the connection region 11a and the other end section 10c-2 of the laminated body in the lamination direction and, further, these two step sections 21A, 21A; 21B, 21B are line-symmetric with respect to a predetermined line PL parallel to the end sections 10c of the laminated body 10 in the lamination direction when the external electrode 11A, 11B is planarly viewed.

For example, as shown in FIGS. 5(A) and 5(B), step sections 21C, 21D are provided by forming rectangular cutouts in end sections of external electrode 11C, 11D in the lamination direction of the laminated body 10 to leave one widthwise end of the external electrode 11C, 11D having a predetermined width when the external electrode 11C, 11D is planarly viewed. In examples shown in FIGS. 5(A) and 5(B), there are two step sections 21C, 21C; 21D, 21D between the boundary 11b of the connection region 11a and the one end section 10c-1 of the laminated body 10 in the lamination direction and between the boundary 11b of the connection region 11a and the other end section 10c-2 of the laminated body in the lamination direction.

In the example shown in FIG. 5A, these two step sections 21C, 21C are line-symmetric with respect to the predetermined line PL parallel to the end sections 10c (10c-1, 10c-2) of the laminated body 10 in the lamination direction when the external electrode 11C is planarly viewed. That is, parts having the predetermined width and left in forming the rectangular cutouts in the external electrode 11C are located on one widthwise end of the external electrode 11C. Further, in the example shown in FIG. 5(B), these two step sections 21D, 21D are point-symmetric with respect to a gravity point GP of the external electrode 11D when the external electrode 11D is planarly viewed. That is, parts having the predetermined width and left in forming the rectangular cutouts in the external electrode 11D are located on one widthwise end of the external electrode 11C on the one end section 10c-1 of the of the laminated body in the lamination direction and located on the other widthwise end of the external electrode 11D at the other end section 10c-2 of the laminated body 10 in the lamination direction.

For example, as shown in FIG. 5(C), two step sections 21E are provided by forming an external electrode 11E with a rectangular cutout extending in the width direction from the other widthwise end of the external electrode 11E and long in the width direction at a position inwardly of and at a predetermined distance from the one end section 10c-1 of the laminated body 10 in the lamination direction when the external electrode 11E is planarly viewed and a rectangular cutout extending in the width direction from one widthwise end of the external electrode 11E and long in the width direction at a position inwardly of and at a predetermined distance from the other end section 10c-2 of the laminated body 10 in the lamination direction when the external electrode 11E is planarly viewed. These two step sections 21E, 21E are point-symmetric with respect to a gravity point GP of the external electrode 11E when the external electrode 11E is planarly viewed.

In the above examples, the two symmetric step sections 21, 21 are provided in terms of performing the bonding step without managing the upper and lower sides of the piezoelectric element 1, but one step section 21 may be provided, for example, as shown in FIGS. 6 and 7.

In examples shown in FIGS. 6(A) and 6(B), a step section 21F, 21G is provided by cutting out a slit in an external electrode 11 substantially at a central position between the both end sections 10c-1, 10c-2 of the laminated body 10 in the lamination direction when the external electrode 11F is planarly viewed. In the case shown in FIG. 6(A), the step section 21F is provided by forming the external electrode 11F with a rectangular cutout extending from one widthwise end of the external electrode 11F and long in the width direction. In the case shown in FIG. 6(B), the step section 21G is provided by cutting a rectangular opening long in the width direction in the external electrode 11G (by forming a rectangular opening long in the width direction in the external electrode 11G).

Further, in an example shown in FIG. 7, a step section 21H is provided by forming a rectangular cutout extending from the one end section 10c-1 of the laminated body 10 in the lamination direction to a substantially central position between the both end sections 10c-1, 10c-2 in an end section of an external electrode 11H in the lamination direction of the laminated body 10 to leave one widthwise end of the external electrode 11H having a predetermined width when the external electrode 11 H is planarly viewed.

By providing such step sections 21, 21A to 21H extending from the lower surface to the higher surface along the flowing direction of the adhesive (including the uncured adhesive) 4, the flow of the adhesive 4 to the connection region 11a is suppressed by blocking the adhesive 4 by the step sections 21, 21A to 21H. Thus, a reduction in the area of the external electrode caused by the flow-out of the adhesive 4 can be suppressed and the connection area for the power supply member on the external electrode 11, 11A to 11H can be more reliably secured.

Note that although the above piezoelectric element 1 is in the form of a rectangular column having a rectangular cross-sectional shape, it may have an arbitrary cross-sectional shape. For example, the piezoelectric element 1 may be in the form of a polygonal column having a polygonal cross-sectional shape, a cylindrical column having a circular cross-sectional shape, an elliptical column having an elliptical cross-sectional shape or the like.

By further including the moving member to be relatively movably and frictionally engaged with the vibrating member 2, such a drive device S can convert elongating and contracting movements of the piezoelectric element 1 into movements of the moving member through reciprocal motion of the vibrating member 2, wherefore the drive device S can be incorporated into various mechanical devices. Particularly, since the piezoelectric element 1 can obtain a large mechanical output for its volume, it can be preferably incorporated into a small-size mechanical device. As an example, a case is described where the drive device S is incorporated into an optical system, for example, to drive a focus lens and/or to drive a zoom lens.

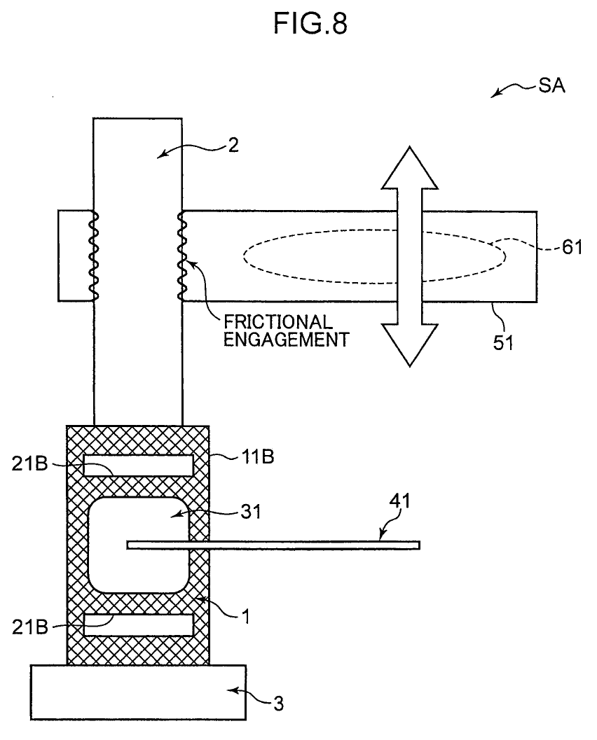

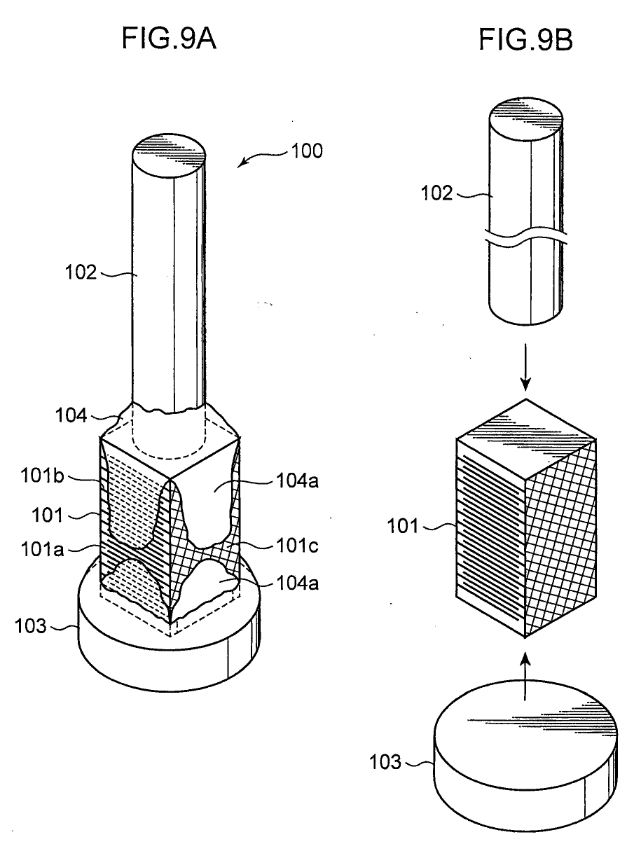

FIG. 8 is a view showing the configuration of a drive device incorporated in an optical system. In FIG. 8, the drive device SA includes a piezoelectric element 1 as an electromechanical conversion element 1, a vibrating member 2 which is fixed to one end section of the piezoelectric element 1 and reciprocates in tandem with elongating and contracting movements of the piezoelectric element 1, a supporting member 3 which is fixed to the other end section of the piezoelectric element 1 and supports the piezoelectric element 1 and the vibrating member 2, and a moving member 51 which is relatively movably and frictionally engaged with the vibrating member 2.

The piezoelectric element 1 is an element formed with any of the external electrodes 11, 11A to 11H described above and including any of the step sections 21, 21A to 21H. In FIG. 8 is shown the piezoelectric element 1 formed with the external electrodes 11B each including two step sections 21B, 21B. A pair of conductive power supply members 41, 41 for supplying power that are conductive by being made of, for example, lead wires or gold wires are connected to connection regions 11a, 11a of a pair of external electrodes 11, 11 of the piezoelectric element 1 by solders 31, 31. The moving member 51 is a circular frame for holding a lens (may be a lens group) 61, for example, a focus lens and/or a zoom lens of the optical system.

In such a drive device SA, when a predetermined voltage is applied from the outside to the pair of external electrodes 11, 11 via the pair of power supply members 41, 41, the piezoelectric element 1 elongates and contracts and the vibrating member 2 reciprocates in tandem with these elongating and contracting movements. By the reciprocal motion of the vibrating member 2, the moving member 51 moves along a longitudinal direction of the vibrating member 2. More specifically, if the piezoelectric element 1 relatively slowly elongates and contracts, the vibrating member 2 also slowly moves and the moving member 51 moves together with the vibrating member 2 while being frictionally engaged with the vibrating member 2. On the other hand, if the piezoelectric element 1 relatively quickly moves, the vibrating member 2 also quickly moves and the moving member 51 slips and displaces relative to the vibrating member 2, trying to remain in position by its own inertial mass. Such an operation is performed, for example, by inputting a voltage having a serrated waveform to the piezoelectric element 1 and causing the vibrating member to vibrate in an asymmetric manner or by inputting a pulse having a rectangular waveform to the piezoelectric element 1 and causing the vibrating member to vibrate in an asymmetric manner by a frequency characteristic of the piezoelectric element 1.

By a movement of the moving member 51 caused by such an operation, focusing is performed, for example, if the lens 61 is a focus lens and zooming is performed, for example, if the lens 61 is a zoom lens. If an imaging element, for example, a CCD image sensor or a CMOS image sensor for converting an optical image into an electrical signal is arranged on an image side of the optical system, an optical image of an object is formed on a light receiving surface of the imaging element by the optical system to be captured.

This description discloses various modes of technologies as described above. Out of them, main technologies are summarized as follows.

An electromechanical conversion element according to one aspect includes a laminated body in which a plurality of piezoelectric layers made of a piezoelectric material and a plurality of conductive internal electrode layers are alternately laminated, and a pair of external electrodes which are formed along a lamination direction on outer peripheral surfaces of the laminated body and successively and alternately electrically connected to the internal electrode layers, wherein a bonding section used to bond a predetermined member is further provided on an end section of the laminated body in the lamination direction, each of the pair of external electrodes has a connection region for connection to a conductive power supply member for supplying power and is formed with a step section having a difference in height between the boundary of the connection region and the end section of the laminated body in the lamination direction.

In such an electromechanical conversion element, in bonding another member to the end section of the electromechanical conversion element in the lamination direction by an adhesive, the adhesive is blocked by the step section and the flow of the adhesive to the connection region is suppressed even if the adhesive flows onto the external electrode. Thus, a reduction in an exposed area for connection, for example, an exposed area for soldering for the power supply member on the external electrode caused by the flow-out of the adhesive can be suppressed, and a connection area for the power supply member on the external electrode can be more reliably secured. The flow-out of the adhesive occurs due to bleed-out as described above, for example, when the adhesive is fixed by being thermally cured. For example, the flow-out occurs when the amount of the adhesive applied to the end section of the electromechanical conversion element or the other member is excessive.

According to another aspect, in the above electromechanical conversion element, there are preferably two step sections between the boundary of the connection region and one end section of the laminated body in the lamination direction and between the boundary of the connection region and the other end section of the laminated body in the lamination direction, and the two step sections are preferably line-symmetric with respect to a predetermined line parallel to the end sections of the laminated body in the lamination direction when the external electrode is viewed in a normal direction to the outer peripheral surface of the laminated body.

According to this configuration, since there are two step sections that are line-symmetric to each other with respect to the predetermined line, a bonding step can be performed, ignoring upper and lower sides of the electromechanical conversion element in the lamination direction, when another member is bonded to the electromechanical conversion element by an adhesive. This bonding step can be performed without managing the upper and lower sides of the electromechanical conversion element in the lamination direction in this way, which is advantageous in manufacturing.

According to another aspect, in the above electromechanical conversion element, there are preferably two step sections between the boundary of the connection region and one end section of the laminated body in the lamination direction and between the boundary of the connection region and the other end section of the laminated body in the lamination direction, and the two step sections are preferably point-symmetric with respect to a gravity point of the external electrode when the external electrode is viewed in a normal direction to the outer peripheral surface of the laminated body.

According to this configuration, since there are two step sections that are point-symmetric to each other with respect to the gravity point of the external electrode, a bonding step can be performed, ignoring upper and lower sides of the electromechanical conversion element in the lamination direction, when another member is bonded to the electromechanical conversion element by an adhesive. This bonding step can be performed without managing the upper and lower sides of the electromechanical conversion element in the lamination direction in this way, which is advantageous in manufacturing.

According to another aspect, in the above electromechanical conversion elements, the step section is preferably a cutout formed in the external electrode.

According to this configuration, the step section can be provided by forming the cutout in the external electrode.

According to another aspect, the above electromechanical conversion elements preferably have a length of about 1 mm in one predetermined direction.

Since the connection region has a relatively small area in such an electromechanical conversion element whose length in the one predetermined direction is about 1 mm, the connection region having only a relatively small area can be secured. Thus, such a configuration can effectively achieve the above effect in relation to the amount of the adhesive.

According to another aspect, in the above electromechanical conversion elements, the difference in height of the step section is preferably about 200 to 600 nm.

According to this configuration, the external electrodes can be relatively easily formed by sputtering.

According to another aspect, in the above electromechanical conversion elements, the difference in height of the step section is preferably about 1 to 50 μm.

According to this configuration, the external electrodes can be relatively easily formed by screen printing.

According to another aspect, in the above electromechanical conversion elements, a pair of conductive power supply members for supplying power are preferably further provided, and the pair of power supply members are preferably connected to the respective connection regions on the pair of external electrodes by solder.

According to this configuration, the electromechanical conversion element is provided in which the pair of power supply members are connected to the pair of external electrodes by soldering.

A drive device according to another aspect includes an electromechanical conversion element, a vibrating member which is fixed to one end section of the electromechanical conversion element by an adhesive and reciprocates in tandem with elongating and contracting movements of the electromechanical conversion element and a moving member which is relatively movably and frictionally engaged with the vibrating member, wherein the electromechanical conversion element is any one of the above electromechanical conversion elements.

Since any one of the above electromechanical conversion elements is used in the drive device configured as described above, failures in connecting the power supply members to the external electrodes are reduced and a yield of drive devices is improved.

A drive device according to another aspect includes an electromechanical conversion element, a vibrating member which is fixed to one end section of the electromechanical conversion element by an adhesive and reciprocates in tandem with elongating and contracting movements of the electromechanical conversion element, a supporting member which is fixed to the other end section of the electromechanical conversion element and supports the electromechanical conversion element and the vibrating member, and a moving member which is relatively movably and frictionally engaged with the vibrating member, wherein the electromechanical conversion element is any one of the above electromechanical conversion elements.

Since any one of the above electromechanical conversion elements is used in the drive device configured as described above, failures in connecting the power supply members to the external electrodes are reduced and a yield of drive devices is improved.

This application is based on Japanese Patent Application Serial No. 2009-289184 filed with the Japan Patent Office on Dec. 21, 2009, the contents of which are hereby incorporated by reference.

The present invention has been appropriately and sufficiently described above to be expressed by way of the embodiment with reference to the drawings, but it should be appreciated that a person skilled in the art can easily modify and/or improve the above embodiment. Accordingly, a modified embodiment or improved embodiment carried out by the person skilled in the art should be interpreted to be embraced by the scope as claimed unless departing from the scope as claimed.

### INDUSTRIAL APPLICABILITY

According to the present invention, it is possible to provide an electromechanical conversion element for converting electrical energy into mechanical energy and a drive device using this electromechanical conversion element.

1. An electromechanical conversion element, comprising:
a laminated body in which a plurality of piezoelectric layers made of a piezoelectric material and a plurality of conductive internal electrode layers are alternately laminated; and
a pair of external electrodes which are formed along a lamination direction on outer peripheral surfaces of the laminated body and successively and alternately electrically connected to the internal electrode layers;
wherein:
a bonding section used to bond a predetermined member is further provided on an end section of the laminated body in the lamination direction; and
each of the pair of external electrodes has a connection region for connection to a conductive power supply member for supplying power and is formed with a step section having a difference in height between the boundary of the connection region and the end section of the laminated body in the lamination direction.

2. An electromechanical conversion element according to claim 1, wherein:
there are two step sections between the boundary of the connection region and one end section of the laminated body in the lamination direction and between the boundary of the connection region and the other end section of the laminated body in the lamination direction; and
the two step sections are line-symmetric with respect to a predetermined line parallel to the end sections of the laminated body in the lamination direction when the external electrode is viewed in a normal direction to the outer peripheral surface of the laminated body.

3. An electromechanical conversion element according to claim 1, wherein:
there are two step sections between the boundary of the connection region and one end section of the laminated body in the lamination direction and between the boundary of the connection region and the other end section of the laminated body in the lamination direction; and
the two step sections are point-symmetric with respect to a gravity point of the external electrode when the external electrode is viewed in a normal direction to the outer peripheral surface of the laminated body.

4. An electromechanical conversion element according to of claim 1, wherein:
the step section is a cutout formed in the external electrode.

5. An electromechanical conversion element according to claim 1, wherein:
the electromechanical conversion element has a length of about 1 mm in one predetermined direction.

6. An electromechanical conversion element according to claim 1, wherein:
the difference in height of the step section is about 200 to 600 nm.

7. An electromechanical conversion element according to claim 1, wherein:
the difference in height of the step section is about 1 to 50 μm.

8. An electromechanical conversion element according claim 1, wherein:
a pair of conductive power supply members for supplying power are further provided; and
the pair of power supply members are connected to the respective connection regions on the pair of external electrodes by solder.

9. A drive device, comprising:
an electromechanical conversion element;
a vibrating member which is fixed to one end section of the electromechanical conversion element by an adhesive and reciprocates in tandem with elongating and contracting movements of the electromechanical conversion element; and
a moving member which is relatively movably and frictionally engaged with the vibrating member,
wherein the electromechanical conversion element is an electromechanical conversion element according to claim 1.

10. A drive device, comprising:
an electromechanical conversion element;
a vibrating member which is fixed to one end section of the electromechanical conversion element by an adhesive and reciprocates in tandem with elongating and contracting movements of the electromechanical conversion element;
a supporting member which is fixed to the other end section of the electromechanical conversion element and supports the electromechanical conversion element and the vibrating member; and
a moving member which is relatively movably and frictionally engaged with the vibrating member;
wherein the electromechanical conversion element is an electromechanical conversion element of claim 1.

11. An electromechanical conversion element according to claim 1, wherein:
a length of the step section in a direction orthogonal to the lamination direction in a plane of the external electrode is equal or longer than a length of the connection region in the direction orthogonal to the lamination direction, and,
the step section is formed at least longer than the connection region in the direction orthogonal to the lamination direction in a plane of the external electrode.
